(19) United States
(12) Patent Application Publication
(10) Pub. No.: US 2010/0052186 A1
(43) Pub. Date: Mar. 4, 2010

(54) STACKED TYPE CHIP PACKAGE STRUCTURE

(75) Inventors: Bernd Karl Appelt, Gulf Breeze, FL (US); Bradford J. Factor, Paris (FR)

Correspondence Address: J C PATENTS, 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/199,130

(22) Filed: Aug. 27, 2008

(51) Int. Cl. H01L 23/48

(52) U.S. Cl. 257/777; 257/E23.01

(57) ABSTRACT

A stacked type chip package structure employs a substrate having a pseudo-cavity or a keep-out zone at one side or both sides thereof. Through the pattern arrangement of the wiring layer and the solder mask layer, the thickness of the entire stacked type chip package structure is effectively reduced as lower wire loops and a thinner mold-cap can be achieved by mounting the chip within the depressed keep-out zone. In particular, the double-sided chip package structures are suitable for package on package structures adopted by mobile applications.

### BACKGROUND OF THE INVENTION

1. Field of the Invention

The present invention relates to a multi-chip package structure. More particularly, the present invention relates to a stacked type chip package structure.

2. Description of Related Art

Multiple-chip package (MCP) structures are commonly used for a variety of applications requiring high performance, low power consumption, and small dimensions. In fact, mobile or portable products demand even thinner package structures with multiple functions.

One potential solution is to employ the package substrate with a cavity (cavity substrate) in the middle for accommodating the chip(s). As shown in FIG. 1, a conventional chip package structure 10 having a cavity 102 mainly includes a carrier substrate 100, a chip 110, a plurality of conductive wires 120, and a molding compound 130. The cavity 102 of the carrier substrate 100 can accommodate the chip 110, while the chip 110 is electrically connected to the pads 106 of the carrier substrate 100 via a plurality of conductive wires 120. The molding compound 130 covers the chip 110 and encapsulates the conductive wires 120. However, the costs of the cavity substrates are high and the design of cavity trims down the layout area for the wires.

Package on package (PoP) structures may be a promising option by stacking a top package on the bottom package for greater space savings. Still, it is imperative to further reduce the total thickness of the chip package structure as the number of the stacked chips keeps escalating and the functions of the electronic devices become more complex day by day.

### SUMMARY OF THE INVENTION

The present invention is directed to a stacked type chip package structure in which the chip is directly mounted on the substrate devoid of the die pad or solder mask in-between, so as to effectively reduce the entire thickness of the stacked type chip package structure.

The present invention is further directed to a double-sided chip package structure in which chips are respectively mounted within the depressed keep-out zones at both sides of the circuit substrate. The double-sided chip package structure is useful for the PoP structures.

In an embodiment of the present invention, a stacked type chip package structure mainly including a first package structure, a second package structure and a plurality of connection structures is described. The first package structure can be a double-sided package structure comprising a multi-layered substrate having at least two circuit layers disposed on two opposite surfaces of the substrate, and a first chip and a second chip respectively disposed on two opposite surfaces of the substrate. In addition, a solder mask layer is respectively formed over two opposite surfaces of the substrate, covering the first circuit layer and the second circuit layer. Through the design of the circuit layer and the solder mask layer at either side of the substrate, a first keep-out zone is defined to accommodate the first chip, while a second keep-out zone is defined to accommodate the second chip. The double-sided package structure further includes a molding compound disposed over two sides of the substrate, whereas the solder mask layer surrounding the ball pads of the circuit layer is uncovered by the molding compound.

In an embodiment of the present invention, the connection structures can be solder balls or gold stud bumps, for example.

In an embodiment of the present invention, the second package structure can be a single chip package structure or a stacked chip package structure.

For the stacked type chip package structure according to the present invention, the thickness of the package structure is greatly reduced as lower wire loops and a thinner mold-cap can be achieved by mounting the chip(s) within the depressed keep-out zone(s) at one side or both side of the substrate. As the mold height of the individual package structure is decreased, smaller interconnected ball sizes or denser ball pitches are allowed, which is especially beneficial for high-density three-dimensional stacked type chip package structures. Further, warpage issues can be improved.

To make the above and other objectives, features, and advantages of the present invention more comprehensible, several embodiments accompanied with figures are detailed as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view illustrating a conventional chip package structure having a cavity.

FIG. 2 is a schematic cross-sectional view of a chip package structure according to one embodiment of the present invention.

FIG. 3 is a schematic cross-sectional view of a double-sided package structure according to another embodiment of the present invention.

FIG. 4 is a schematic cross-sectional view of a stacked type chip package structure according to another embodiment of the present invention.

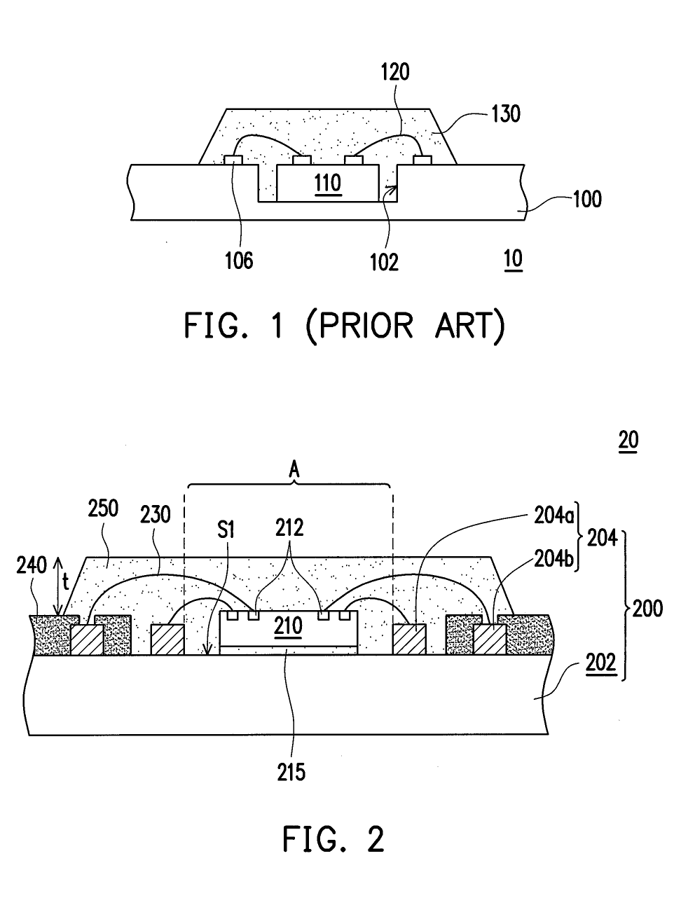

### DESCRIPTION OF EMBODIMENTS

FIG. 2 is a schematic cross-sectional view of a chip package structure according to one embodiment of the present invention. The chip package structure 20 comprises a substrate 200, at least a chip 210, a plurality of conductive wires 230 and a molding compound 250. The substrate 200, for example, can be a multi-layered substrate having at least a base 202 and a patterned metal layer 204 disposed on the top surface S1 of the base 202. The patterned metal layer 204 forms a circuit (or wiring) layer having a plurality of pads 204a and traces 204b. The substrate 200 can be a multi-layer circuit substrate, such as a two-layer circuit substrate, a four-layer circuit substrate, or a six-layer circuit substrate, for example. The metal layer 204 may be formed by electroplating or laminating copper or copper foil onto the base 202, for example. The base 202 not only can serve as an insulated core base, but also can have built-up circuits or laminated circuits in which the insulation material is laminated.

The contacts 212 of the chip 210 are respectively electrically connected to the pads 204a and/or traces 204b via a plurality of conductive wires 230. The chip 210 is adhered to the top surface S1 of the base 202 through an adhesive 215. Preferably, the adhesive 215 can be a die attach film, for example, with or without fillers for thermal enhancement. A patterned solder mask layer 240 partially covers the circuit layer 204 to expose the pads 204a and the traces 204b for further electrical connections. The solder mask 240 is, for example, formed by stencil printing, roller coating, dry film lamination or spin coating, to partially cover the circuit layer 204. A portion of the circuit layer 204 which is covered by the solder mask layer 240 is protected from subsequent soldering or wire-bonding. The molding compound or encapsulant 250 covers the chip 210 and encapsulates the conductive wires 230. The mold-cap thickness of the molding compound 250 for the package structure 20 is mainly controlled by the wire-bonding height and the thickness of the underlying chip 210.

The design of the above package structure 20 is to keep the circuit layer 204 and the solder mask layer 240 out from the location of the chip 210. That is, through the arrangement of the patterned metal layer 204 and the patterned solder mask layer 240, there is a cavity-like region or a keep-out zone A to accommodate the chip 210 and the chip is adhered to the exposed base 202 in the keep-out zone A. Hence, the portion of the substrate 200 that is directly underneath the chip 210 is free of wiring layer (including so-called die pad) and the solder mask layer. The size of the keep-out zone A is substantially equivalent to the die shadow or slightly larger than the size of the die.

Basically, the mold-cap thickness t of the molding compound 250 can be slightly larger (i.e. higher) than the wire-bonding height of the conductive wires 230. The keep-out zone A is considered depressed because there is a height difference between the bare surface of the base 202 and the top surface of the solder mask layer and/or the wiring layer. Compared the package structure 20 with the conventional package structure having the chip on the die pad that is covered with the solder mask, the depressed keep-out zone A can be regard as lowering the position of the chip up to 80 microns (i.e. if counting the total thickness of the die pad plus the solder mask in the conventional package structure). By adding two layers of soldermask or increasing the trace height, the depth of the depressed zone can be increased to well over 100 microns. In our design, the depressed keep-out zone A lowers the position of the chip 210 and correspondingly the wire loops. Due to the lower wire loop height, a thinner molding compound is formed and the total thickness of the above package structure is clearly reduced.

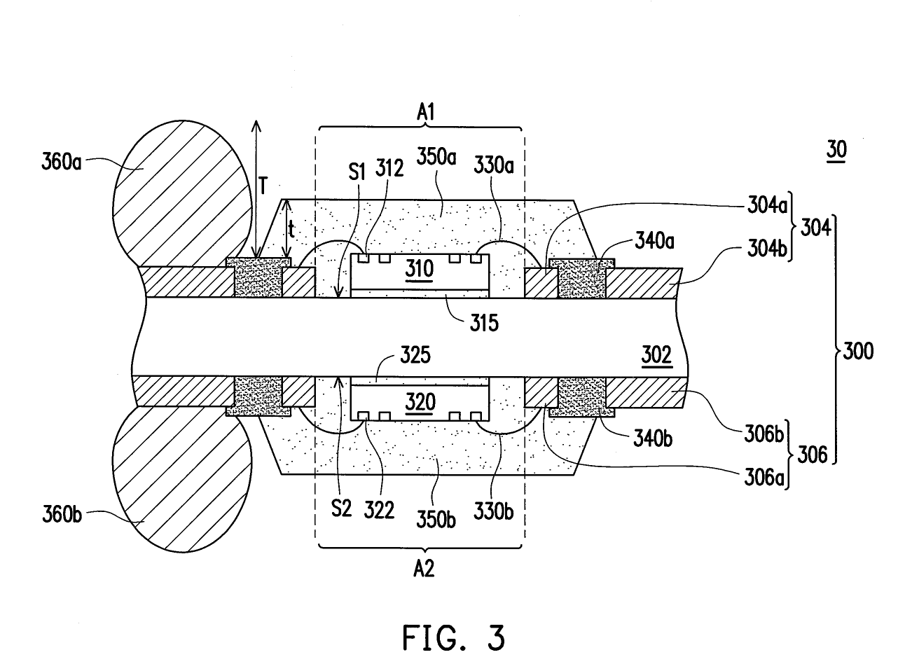

FIG. 3 is a schematic cross-sectional view of a double-sided package structure according to another embodiment of the present invention. The double-sided chip package structure 30 comprises a double-sided substrate 300, a first chip 310 disposed on a first surface S1 of the substrate 300, a second chip 320 disposed on a second surface S2 of the substrate 300, a plurality of first conductive wires 330a, a plurality of second conductive wires 330b, and a molding compound 350a, 350b covering respectively the first chip 310 and the second chip 320.

In FIG. 3, the substrate 300, for example, can be a multi-layered substrate having at least a base 302 and a first patterned metal layer 304, a second patterned metal layer 306 respectively disposed on the top surface S1, bottom surface S2 of the base 302. The first patterned metal layer 304 forms a circuit (or wiring) layer having a plurality of pads 304a and ball pads 304b, while the second patterned metal layer 306 forms a circuit (or wiring) layer having a plurality of pads 306a and ball pads 306b. The multi-layer circuit substrate 300 is preferably a four-layer circuit substrate (such as, 4L or 1+2+1 layered substrate), a six-layer circuit substrate (such as, 6L, 2+2+2 or 1+4+1 layered substrate) or a circuit substrate of higher layer counts, for example. The contacts 312 of the first chip 310 are respectively electrically connected to the pads 304a via the conductive wires 330a. The contacts 322 of the second chip 320 are respectively electrically connected to the pads 306a via the conductive wires 330b. The first chip 310 is adhered to the top surface S1 of the base 302 through an adhesive 315, while the second chip 320 is adhered to the bottom surface S2 of the base 302 through an adhesive 325. Similarly, the adhesive 315 or 325 can preferably be a die attach film, for example, with or without thermally enhanced fillers.

A first patterned solder mask layer 340a exposes the pads 304a and the ball pads 304b for further electrical connections, and at least a first solder ball 360a is disposed on the ball pad 304b. A second patterned solder mask layer 340b exposes the pads 306a and the ball pads 306b for further electrical connections, and at least a second solder ball 360b is disposed on the ball pad 306b. The solder mask layer 340a/340b partially covers the circuit layer 304/306 to protect traces (not shown) from subsequent soldering or wire-bonding. The first molding compound 350a covers the first chip 310 and encapsulates the conductive wires 330a, while the second molding compound 350b covers the second chip 320 and encapsulates the conductive wires 330b. The molding compound 350a/b may extend onto the solder mask layer 340a/b.

Following the design of the above package structure 20 by keeping the locations of the chips clear or free of wirings and solder mask, there is a keep-out zone A1 present to accommodate the chip 310 and the chip 310 is adhered to the top surface S1 of the exposed base 302 in the keep-out zone A1. Also, there is a keep-out zone A2 present to accommodate the chip 320 and the chip 320 is adhered to the bottom surface S2 of the exposed base 302 in the keep-out zone A2. As shown in FIG. 3, the keep-out zone A1 is substantially aligned with the keep-out zone A2. However, it is unnecessary that the sizes of the keep-out zone A1 and A2 are the same or the locations of both line up.

According to this embodiment, the thickness of the solder mask layer 340a/340b defines the depth of the cavity-like region or keep-out zone A1/A2 for receiving the chip 310/320 and the stand-off height T of the solder balls 360a/360b. Attributable to the depressed keep-out zone A1/A2, the package structure 30 possesses lower wire loops and a thinner molding compound.

For further reducing the dimensions and thickness of package products, the above single sided package structure 20 or double-sided package structure 30 can be further applied in the package on package (PoP) structure. In principle, for the PoP structure, the top package is interconnected to the bottom package through solder balls around the periphery of the bottom package. For example, the top package is a single die BGA or stacked die BGA package, and the bottom package usually contains a logic device or sometimes also stacked die.

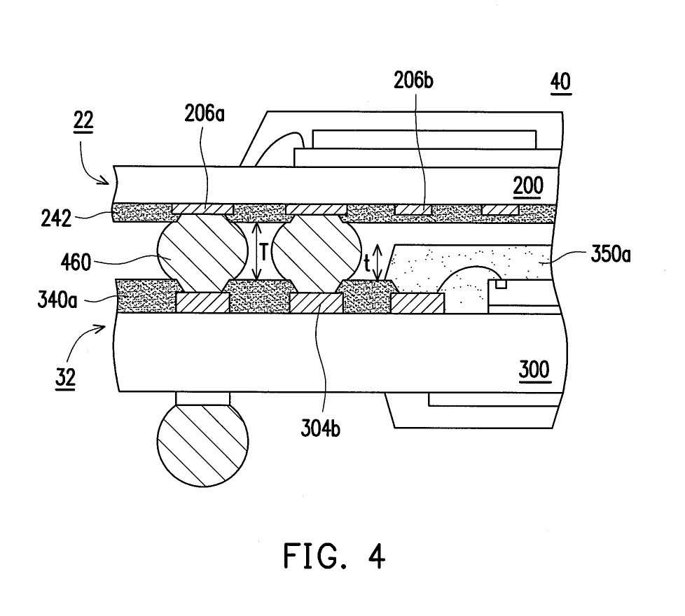

FIG. 4 is a schematic cross-sectional view of a stacked chip package structure according to another embodiment of the present invention. Herein, a double-sided package structure is used as the bottom package of the PoP structure. However, the double-sided package structure can also be used as the top package, depending on the design of the PoP structure, i.e. depending on how many packages are being stacked. As shown in FIG. 4, in the PoP structure 40, two individual package structures 32 and 22 are provided, and then the two package structures 32 and 22 are adhered and electrically connected to each other through a plurality of connection structures 460 to form the PoP structure 40. The package structure 22 is similar to the above package structure 20, except that the back surface of the substrate 200 is covered by a patterned solder mask layer 242 which covers the traces 206b but exposes the ball pads 206a for receiving connection structures 460. The package structure 32 is similar to the above double-sided package structure 30, and the solder mask layer 340a exposes the ball pads 304b for receiving connection structures 460. The connection structures 460 connected to the ball pads 206a and 304b can be, for example, solder balls formed by reflowing. Copper pillars or gold studs can also be used as connection structures by reflowing with solder materials. The total thickness of the connection structure 460 and the ball pads 206a and 304b has to be larger than the sum of a thickness of the solder mask layer 242 and a thickness of the molding compound 350a.

The gold studs or Cu pillars can be firstly arranged on the pads of the bottom package structure and then reflowed with the solder paste formed on the ball pads of the top package, which is beneficial for reworking as the gold studs remain intact after the removal of the top package. Alternatively, the gold studs can be firstly arranged on the pads of the top package structure and then reflowed with the solder paste formed on the ball pads of the bottom package. For the stacked package structure, the connection structures can be arranged on a perimeter of the top surface of the bottom PoP package.

As discussed above, the thickness of the solder mask layer 242 or 340a defines the depth of the cavity-like region or keep-out zone for receiving the chip and the stand-off height T of the connection structures 460. If necessary, the thickness of the solder mask layer can be adjusted by increasing the coating thickness or even doubling the layers according to the thickness of the chip or the total thickness of the stacked chips. To enable package stacking for the PoP structure, the mold-cap thickness t of the bottom package must be less than the standoff height T of the connection structure between the stacked packages. In this case, smaller sized solder ball or studs can be used due to the low-profile bottom package structure. Also, smaller solder balls or studs allow a denser ball pitch for the stacked type chip package. On the other hand, if using the solder ball or studs in standard sizes, integration of multiple die and/or larger die in the bottom package may be feasible for PoP packages. Aside from easy reworkability, the major advantage of gold studs and copper pillars is that their smaller diameters (when compared with solder balls) allow smaller pitch of the interconnects, thereby increasing the number of interconnects per unit area.

To sum up, in the present invention, the thickness of the entire stacked type chip package structure is effectively reduced as lower wire loops and a thinner mold-cap can be achieved by mounting the chip(s) within the keep-out zone (i.e. void or opening defined by the surrounding wiring and solder mask layer).

Although the present invention has been disclosed by the above embodiments, they are not intended to limit the present invention. Anybody skilled in the art may make some modifications and alterations without departing from the spirit and scope of the present invention. Therefore, the protection range of the present invention falls in the appended claims.

What is claimed is:

1. A stacked type chip package structure, comprising:
a first package structure comprising:
a first substrate having a base, a first circuit layer disposed on a first surface of the base, and a second circuit layer disposed on a second surface of the base opposite to the first surface, wherein the first circuit layer comprises a plurality of first ball pads and defines a first keep-out zone, while the second circuit layer defines a second keep-out zone;
a first mask layer over the first circuit layer, wherein the first mask layer exposes the first keep-out zone and the first ball pads;
a first chip disposed on the first surface of the base within the first keep-out zone, and electrically connected to the first substrate;
a first molding compound encapsulating the first chip, wherein the first molding compound partially covers the first circuit layer and the first mask layer, while the first ball pads and the first mask layer that surrounds the first ball pads are uncovered by the first molding compound;
a second mask layer over the second circuit layer, wherein the second mask layer exposes the second keep-out zone;
a second chip disposed on the second surface of the base within the second keep-out zone, and electrically connected to the first substrate; and
a second molding compound encapsulating the second chip;
a second package structure comprising:
a second substrate having a plurality of second ball pads disposed on a back surface of the second substrate;
a third chip disposed on a carrying surface of the second substrate and electrically connected to the second substrate;
a third mask layer covering the back surface of the second substrate but exposing the second ball pads; and
a third molding compound encapsulating the third chip; and
a plurality of connection structures, each disposed between the first ball pad and the second ball pad for electrically connecting the first package structure and the second package structure.

2. The stacked type chip package structure as claimed in claim 1, wherein the connection structure is a solder ball, a gold stud bump, or a copper pillar.

3. The stacked type chip package structure as claimed in claim 1, wherein the second package structure further comprises a fourth chip stacked directly on the third chip.

4. The stacked type chip package structure as claimed in claim 1, wherein the first circuit layer further comprises at least a first pad and the first chip is electrically connected to the first pad through wire-bonding.

5. The stacked type chip package structure as claimed in claim 1, wherein the second circuit layer further comprises at least a second pad and the second chip is electrically connected to the second pad through wire-bonding.

6. The stacked type chip package structure as claimed in claim 1, wherein the first substrate is a four-layered or a six-layered circuit board.

7. The stacked type chip package structure as claimed in claim 1, wherein the first ball pads are arranged along a perimeter of the first substrate.

8. The stacked type chip package structure as claimed in claim 1, wherein the first chip is attached to the base through an adhesive film, and the second chip is attached to the base through an adhesive film.

9. The stacked type chip package structure as claimed in claim 1, wherein a total thickness of the connection structure, the first ball pad and the second ball pad is larger than the sum of a thickness of the third mask layer and a thickness of the first molding compound.

10. The stacked type chip package structure as claimed in claim 1, wherein the first keep-out zone is free of the first circuit layer and the first mask layer, and the second keep-out zone is free of the second circuit layer and the second mask layer.

11. A chip package structure, comprising:
a substrate having a base, a first circuit layer disposed on a first surface of the base, wherein the first circuit layer comprises a plurality of first ball pads and a plurality of first contact pads and defines a first keep-out zone;
a first solder mask layer partially covering the first circuit layer, but exposing the first keep-out zone, the first contact pads and the first ball pads;
a first chip disposed on the first surface of the base within the first keep-out zone, and electrically connected to the first contact pads of the substrate through a plurality of first wires; and
a first molding compound encapsulating the first chip and the first wires, wherein the first molding compound partially covers the first circuit layer and the first solder mask layer, while the first ball pads and the first mask layer that surrounds the first ball pads are uncovered by the first molding compound.

12. The chip package structure of claim 11, further comprising a plurality of connection structures disposed on the first ball pads.

13. The chip package structure of claim 12, wherein the connection structure is a solder ball, a gold stud bump, or a copper pillar.

14. The chip package structure of claim 11, further comprising:
a second circuit layer disposed on a second surface of the base opposite to the first surface of the base, wherein the second circuit layer comprises a plurality of second ball pads and a plurality of second contact pads and defines a second keep-out zone;
a second solder mask layer partially covering the second circuit layer, but exposing the second keep-out zone, the second contact pads and the second ball pads;
a second chip disposed on the second surface of the base within the second keep-out zone, and electrically connected to the second contact pads of the substrate through a plurality of second wires; and
a second molding compound encapsulating the second chip and the second wires, wherein the second molding compound partially covers the second circuit layer and the second solder mask layer, while the second ball pads and the second mask layer that surrounds the second ball pads are uncovered by the second molding compound.

15. The chip package structure of claim 14, further comprising a plurality of connection structures disposed on the second ball pads.

16. The chip package structure of claim 15, wherein the connection structure is a solder ball, a gold stud bump, or a copper pillar.

17. The chip package structure of claim 11, wherein the substrate is a four-layered or a six-layered circuit board.

18. The chip package structure of claim 11, wherein the first chip is attached to the base through an adhesive film.

19. The chip package structure of claim 14, wherein the second chip is attached to the base through an adhesive film.

20. The chip package structure of claim 14, wherein the first keep-out zone is free of the first circuit layer and the first solder mask layer, while the second keep-out zone is free of the second circuit layer and the second solder mask layer.
